(19) United States
(12) Patent Application Publication
(10) Pub. No.: US 2022/0147672 A1
(43) Pub. Date: May 12, 2022

(54) METHOD AND SYSTEM FOR ADAPTIVE LEARNING OF MODELS FOR MANUFACTURING SYSTEMS

(71) Applicant: TATA CONSULTANCY SERVICES, Mumbai (IN)

(72) Inventors: SRI HARSHA NISTALA, Pune (IN); RAJAN KUMAR, Pune (IN); JAYASREE BISWAS, Pune (IN); CHETAN JADHAV, Pune (IN); ABHISHEK BAIKADI, Pune (IN); VENKATARAMANA RUNKANA, Pune (IN); ROHAN PANDYA, Pune (IN)

(73) Assignee: Tata Consultancy Services Limited, Mumbai (IN)

(21) Appl. No.: 17/595,434

(22) PCT Filed: May 17, 2020
(86) PCT No.: PCT/IN2020/050446

§ 371 Date: Nov. 16, 2021

(30) Foreign Application Priority Data
May 17, 2019 (IN) 201921019548

(51) Int. Cl. G06F 30/27; G06Q 50/04; G06Q 10/06

(52) U.S. Cl. CPC G06F 30/27; G06Q 10/0637; G06Q 50/04

(57) ABSTRACT

This disclosure relates to a method and system for adaptive learning of physics-based models, data-driven models and hybrid models used in an industrial manufacturing plant. A model-based optimization and advisory device (MOAD) is configured for monitoring performance of data-driven and physics-based models of industrial process units in real-time, computing model quality index for models, triggering adaptive learning of these models and in case of drift in predictions, diagnosing the reasons for drift in predictions. Suggesting re-tuning, re-building, and recreating of the models to achieve highest prediction quality, and automatic deployment of latest models. The method and system ensures that the models of industrial manufacturing plant that provide critical operational decisions to the operators are kept up-to-date with minimal human intervention, while ensuring that adaptive learning is executed only when required and not on the basis of the amount of newer operational data accumulated or the time elapsed since model deployment.

### CROSS-REFERENCE TO RELATED APPLICATIONS AND PRIORITY

The present application claims priority from Indian provisional patent application number 201921019548, filed on May 17, 2019. The entire contents of the aforementioned application are incorporated herein by reference.

### TECHNICAL FIELD

The disclosure herein generally relates to the field of industrial data analytics and specifically, to a method and system for adaptive learning of physics-based models, data-driven models and hybrid physics plus data-driven models used in an industrial manufacturing plant.

### BACKGROUND

Indicators such as productivity, product quality, energy consumption, plant availability, maintenance expenditure, percentage of emergency work, etc. are used to monitor the performance of manufacturing industries and process plants. Industries today face the challenge of meeting ambitious production targets, minimizing their energy consumption, meeting emission standards and customizing their products, while handling wide variations in raw material quality. Industrial manufacturing plants strive to continuously improve their performance indicators by modulating few parameters that are known to influence them.

Model based optimization and control is a powerful approach to optimize industrial key performance indicators (KPIs), particularly when multiple KPIs and complex processes comprising of multiple process steps are involved. In this approach, optimization is carried out on models that mimic the behavior of industrial processes to arrive at optimum set points that can be suggested to the operators/plant engineers. The models used for optimization can be physics-based models (e.g. heat and mass balance, Computational Fluid Dynamics (CFD) models, force balance models, etc.) or data-driven or machine learning models (e.g. regression models, artificial neural network models, classification models, anomaly/fault detection models, anomaly/fault diagnosis models, anomaly/fault prognosis models) or a combination of both, i.e. hybrid physics plus data-driven models. These models predict the response of industrial processes or equipment in real-time using important variables related to the processes or equipment. Such models can be used for performing real time process monitoring, diagnostics, optimization and control.

The performance of physics-based models or data-driven models deployed in industrial manufacturing plants may deteriorate over time due to factors such as changes in equipment/plant due to maintenance activities, ageing (wear and tear) of equipment, changes in operating strategy of the plant, changes in raw materials/inputs, malfunctioning (or failure) of key sensors and process/equipment abnormalities. Due to these reasons, the model predictions may drift leading to drop in performance accuracy of the model. In such cases, the models would not be effective for carrying out online monitoring, diagnostics and optimization. In cases, where the key sensors fail or the process is abnormal, model predictions would not be generated, leading to failure of the online monitoring, diagnostics and optimization procedure.

### SUMMARY

Embodiments of the disclosure present technological improvements as solutions to one or more of the above-mentioned technical problems recognized by the inventors in conventional systems. For example, in one embodiment, a system and method for adaptive learning of a plurality of models of industrial manufacturing plants is provided.

In one aspect, a processor-implemented method for adaptive learning of a plurality of models of industrial manufacturing plant is provided. The method includes one or more steps such as receiving a plurality of data from one or more databases of an industrial manufacturing plant at a pre-determined frequency, and pre-processing the received plurality of data for verification of availability of received plurality of data, removal of redundant data, unification of sampling frequency, identification and removal of outliers, imputation of missing data, and synchronization and integration of a plurality of variables from one or more databases.

The processor-implemented method includes obtaining simulated data based on the pre-processed data and at least one soft sensor, combining the simulated data with pre-processed data to obtain integrated data, determining one or more predicted values of each of the plurality of response variables using the obtained integrated data and a plurality of models. Herein, it is to be noted that the plurality of models comprising at least one active model. A model quality index (MQI) is computed for each of the plurality of models using the one or more predicted values and actual values of each of the one or more response variables, a drift in performance of each of the plurality of models is determined based on one or more predefined thresholds of MQI. Further, at least one cause of the determined drift in the performance of the plurality of models is identified using the one or more key performance parameters related to the industrial manufacturing plant.

Further, the processor-implemented method comprises selection of a first set of data and a second set of data of the industrial manufacturing plant, wherein the first set of data comprises of real-time and non-real-time data used for training of the plurality of models and second set of data comprises of real-time and non-real-time data since activation of the plurality of models. Further, a pre-adaptive learning is activated to compute MQI for each of subset of plurality of models on the selected the first set of data and the second set of data based on the identified cause of the drift in the performance of the plurality of models and an adaptive learning is triggered based on the computed MQI of each of the subset of the plurality of models on the selected the first set of data and the second set of data when MQI is below the one or more predefined MQI thresholds. It would be appreciated that the adaptive learning of the plurality of models includes model performance diagnosis, model re-tuning, model re-building, and model re-creating on the selected the first set of data and the second set of data. Finally, at least one model for activation in the industrial manufacturing plant is recommended based on the adaptive learning of the plurality of models. The at least one model includes a re-tuned model, a re-built model, and a re-created model.

In another aspect, a system for adaptive learning of a plurality of models of industrial manufacturing plant is provided. The system includes an input/output interface configured to receive a plurality of data from one or more databases of an industrial manufacturing plant at a pre-determined frequency, at least one memory storing a plurality of instructions and one or more hardware processors communicatively coupled with the at least one memory, wherein the one or more hardware processors are configured to execute the plurality of instructions stored in the at least one memory. Further, the system is configured to receive a plurality of data from the one or more databases of the manufacturing plant at a pre-determined frequency, to pre-process the received plurality of data for verification of availability of received plurality of data, removal of redundant data, unification of sampling frequency, identification and removal of outliers, imputation of missing data, and synchronization and integration of a plurality of variables from one or more databases. Further, the system is configured to obtain simulated data based on the pre-processed data and at least one soft sensor, and combine the simulated data with pre-processed data to obtain integrated data, and to determine one or more predicted values of each of the plurality of response variables using the obtained integrated data and a plurality of models.

Furthermore, the system is configured to compute a model quality index (MQI) for each of the plurality of models using various predicted values and actual values of each of the one or more response variables and to determine a drift in performance of each of the plurality of models based on one or more predefined thresholds of MQI. It is to be noted that the computed MQI of each of the plurality of models is compared with the predefined thresholds of MQI for each of the plurality of models. Furthermore, the system is configured to identify at least one cause of the determined drift in the performance of the plurality of models using the one or more key performance parameters related to the industrial manufacturing plant.

Further, the system is configured to select a first set of data and a second set of data, to activate a pre-adaptive learning to compute MQI for each of subset of plurality of models on the selected the first set of data and the second set of data based on the identified cause of the drift in the performance of the plurality of models. An adaptive learning process is triggered based on the computed MQI of each of the subset of the plurality of models when computed MQI is below the one or more predefined MQI thresholds. Herein, the adaptive learning of the plurality of models includes model performance diagnosis, model re-tuning, model re-building, and model-recreating on the selected the first set of data and the second set of data. Finally, the system is configured to recommend at least one model for activation in the industrial manufacturing plant based on the adaptive learning of the plurality of models, wherein the at least one model includes a re-tuned model, a re-built model and a re-created model.

In yet another aspect, a non-transitory computer readable medium for adaptive learning of a plurality of models of industrial manufacturing plant is provided. The non-transitory computer readable medium includes one or more instructions such as receiving a plurality of data from one or more databases of an industrial manufacturing plant at a pre-determined frequency, and pre-processing the received plurality of data for verification of availability of received plurality of data, removal of redundant data, unification of sampling frequency, identification and removal of outliers, imputation of missing data, and synchronization and integration of a plurality of variables from one or more databases.

The non-transitory computer readable medium includes obtaining simulated data based on the pre-processed data and at least one soft sensor, combining the simulated data with pre-processed data to obtain integrated data, determining one or more predicted values of each of the plurality of response variables using the obtained integrated data and a plurality of models. Herein, it is to be noted that the plurality of models comprising at least one active model. A model quality index (MQI) is computed for each of the plurality of models using the one or more predicted values and actual values of each of the one or more response variables, a drift in performance of each of the plurality of models is determined based on one or more predefined thresholds of MQI. Further, at least one cause of the determined drift in the performance of the plurality of models is identified using the one or more key performance parameters related to the industrial manufacturing plant.

Further, the non-transitory computer readable medium comprises selection of a first set of data and a second set of data of the industrial manufacturing plant, wherein the first set of data comprises of real-time and non-real-time data used for training of the plurality of models and second set of data comprises of real-time and non-real-time data since activation of the plurality of models. Further, a pre-adaptive learning is activated to compute MQI for each of subset of plurality of models on the selected the first set of data and the second set of data based on the identified cause of the drift in the performance of the plurality of models and an adaptive learning is triggered based on the computed MQI of each of the subset of the plurality of models on the selected the first set of data and the second set of data when MQI is below the one or more predefined MQI thresholds. It would be appreciated that the adaptive learning of the plurality of models includes model performance diagnosis, model re-tuning, model re-building, and model re-creating on the selected the first set of data and the second set of data. Finally, at least one model for activation in the industrial manufacturing plant is recommended based on the adaptive learning of the plurality of models. The at least one model includes a re-tuned model, a re-built model, and a re-created model.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this disclosure, illustrate exemplary embodiments and, together with the description, serve to explain the disclosed principles:

FIG. 1 illustrates an exemplary system for adaptive learning of models of an industrial manufacturing plant, according to an embodiment of the present disclosure.

FIG. 2 illustrates a system for adaptive learning of models of an industrial manufacturing plant, according to an embodiment of the present disclosure.

FIG. 3 is a functional block diagram to illustrate model performance monitoring of a plurality of models of the industrial manufacturing plant, according to an embodiment of the present disclosure.

FIG. 4 is a schematic diagram to show model quality index thresholds, according to an embodiment of the present disclosure

FIG. 5 is a functional block diagram to illustrate creation of adaptive learning knowledge base, according to an embodiment of the present disclosure.

FIG. 6 is a schematic diagram to show static and dynamic databases in the adaptive learning knowledge base, according to an embodiment of the present disclosure.

FIG. 7 is a workflow to illustrate an adaptive learning module of the system, according to an embodiment of the present disclosure.

FIG. 8 is a functional block diagram to illustrate a model diagnosis according to an embodiment of the present disclosure.

FIG. 9 is a schematic diagram to show training dataset generation and re-tuning of models, according to an embodiment of the present disclosure.

FIG. 10 is a schematic diagram to illustrate a model re-building, according to an embodiment of the present disclosure.

FIG. 11 is a schematic diagram to illustrate a model re-creating, according to an embodiment of the present disclosure.

FIG. 12 is a flow diagram to illustrate a method for adaptive learning of models of a plant or manufacturing system, in accordance with some embodiments of the present disclosure.

### DETAILED DESCRIPTION OF EMBODIMENTS

Exemplary embodiments are described with reference to the accompanying drawings. In the figures, the left-most digit(s) of a reference number identifies the figure in which the reference number first appears. Wherever convenient, the same reference numbers are used throughout the drawings to refer to the same or like parts. While examples and features of disclosed principles are described herein, modifications, adaptations, and other implementations are possible without departing from the spirit and scope of the disclosed embodiments. It is intended that the following detailed description be considered as exemplary only, with the true scope and spirit being indicated by the following claims.

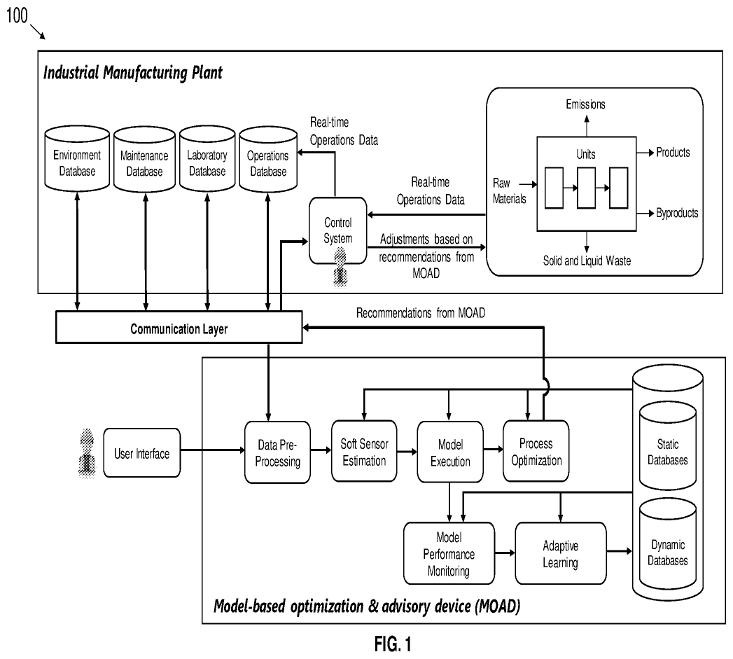

Referring now to the drawings, and more particularly to FIG. 1 through 12, where similar reference characters denote corresponding features consistently throughout the figures, there are shown preferred embodiments and these embodiments are described in the context of the following exemplary system and/or method.

Referring FIG. 1, illustrates an exemplary system for adaptive learning of models of an industrial manufacturing plant. It would be appreciated that the industrial manufacturing plant herein refers to a processing plant or a manufacturing plant that comprises of processing units in series or parallel. The industrial manufacturing plant processes inputs in the form of raw materials, generates products, byproducts, and, possibly solid & liquid waste and gaseous emissions. The industrial manufacturing plant usually operates in an environment, and environment conditions such as ambient temperature, pressure and humidity typically influence the operation of the plant. A model-based optimization and advisory device (MOAD) interacts with the plant via a communication layer and receives real-time and non-real-time data from several industrial manufacturing plant databases such as operations database, laboratory database, maintenance database, environment database and the like. It pre-processes the plant data, obtains simulated data using the pre-processed data and soft sensors, combines simulated data and pre-processed data to obtain integrated data, and uses the integrated data to provide services such as prediction, classification, detection, diagnosis and prognosis, process optimization, model monitoring and adaptive learning for active models (that can be physics-based, data-driven or hybrid) either continuously or on demand depending on its configuration. The outputs of various services are shown to the user via various interfaces that are part of the MOAD.

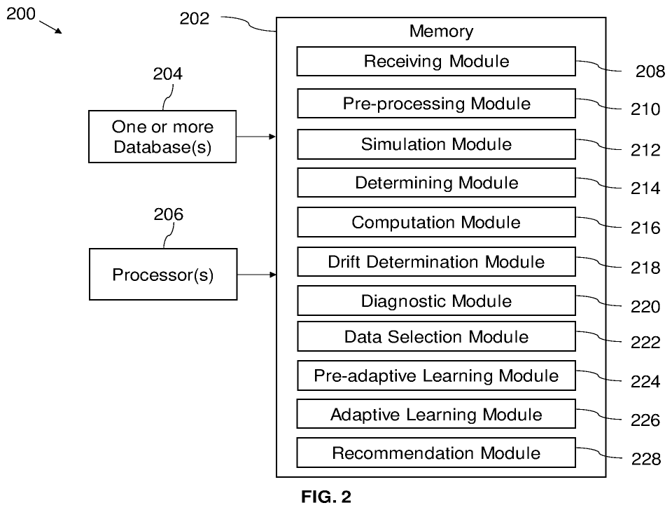

Referring FIG. 2, a system (200) is configured for adaptive learning of models of the industrial manufacturing plant. The system (200) comprises at least one memory (202) with a plurality of instructions, one or more databases (204) and one or more hardware processors (206) which are communicatively coupled with the at least one memory (202) to execute a plurality of modules therein. Further, the system comprises a receiving module (208), a pre-processing module (210), a simulation module (212), a determining module (214), a computation module (216), a drift determination module (218), a diagnostic module (220), a data selection module (222), a pre-adaptive learning module (224), an adaptive learning module (226), and a recommendation module (228).

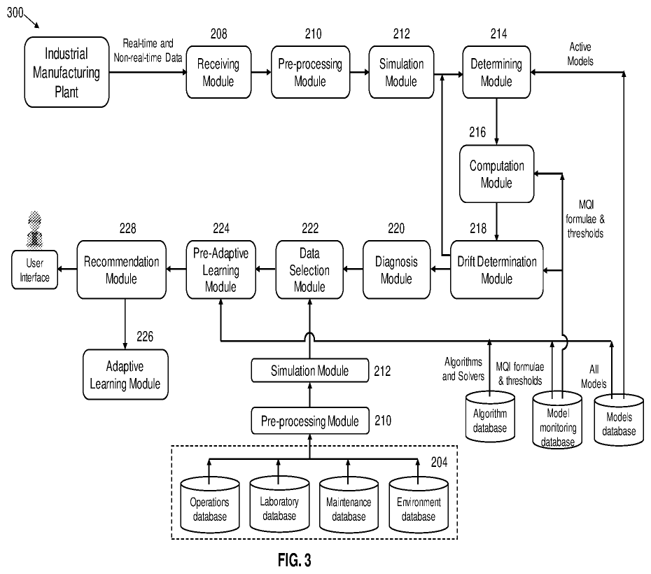

Referring FIG. 3, wherein a functional block diagram to illustrate one or more modules of the system (200). Herein, the receiving module (208) is configured to receive real-time and non-real-time data from various databases in the industrial manufacturing plant at a pre-determined frequency (e.g. 1/second, 1/minute, 1/hour, etc.; frequency is configurable by the user). Real-time data includes operations data and environment data. Operations data is recorded by sensors in the plant and includes temperatures, pressures, flow rates and vibrations from processes and equipment in the units of the plant. Operations data is obtained from a distributed control system (DCS), OPC server, etc. and is stored in an operations database or historian. Environment data such as ambient temperature, atmospheric pressure, ambient humidity, rainfall, etc. is also recorded by sensors and is stored in an environment database. Non-real-time data includes data from the laboratories and maintenance activities. Laboratory data comprises of characteristics (e.g. chemical composition, size distribution, concentration, density, viscosity, calorific value, microstructural composition, etc.) of raw materials, products, byproducts, solid and liquid waste, and emissions that are tested at the laboratory. Laboratory data is typically stored and retrieved from a laboratory information management system (LIMS), relational database (RDB) or SQL database. Information related to the condition of the process and equipment, plant running status, maintenance activities performed on the plant units, etc. is stored and retrieved from a maintenance database.

In the preferred embodiment, the pre-processing module (210) of the system (200) is configured to perform pre-processing of the real-time and non-real-time data received from multiple databases of the industrial manufacturing plant. Pre-processing involves removal of redundant data, unification of sampling frequency, outlier identification & removal, imputation of missing data, synchronization and integration of variables from multiple data sources.

In the preferred embodiment, the simulation module (212) of the system (200) is configured to obtain simulated data based on the pre-processed data and at least one soft sensor. Wherein the at least one soft-sensor comprises a physics-based soft sensor and a data-driven soft sensor, wherein the simulated data is integrated with pre-processed data to obtain integrated data. Soft sensors are parameters that have an impact on the key performance parameters of the plant but are not measured or cannot be measured using physical sensors. Examples of soft sensors include temperature in the firing zone of a furnace, concentration of product or byproducts inside a reactor, etc.

In the preferred embodiment, the determining module (214) of the system (200) configured to determine one or more predicted values of each of the plurality of response variables using the obtained integrated data and a plurality of models. The plurality of models comprising at least one active model. Herein, the determining module (214) performs prediction on the real-time data using the active prediction, detection, classification, diagnosis or prognosis models to obtain, for example, a predicted value of a response variable, to detect and diagnose process and equipment anomalies, to classify the state of the process of equipment or to estimate remaining useful life (or time-to-failure) for the process and equipment. The active models can use some or all the variables received from the plant for predictions.

It would be appreciated that the active models can be physics-based models, data-driven models or hybrid models that are a combination of physics-based and data-driven models. Physics-based models include zero-dimensional, one-dimensional, two-dimensional, three-dimensional or lumped-parameter implementations of heat and mass balance models, computational fluid dynamic models or force balance models or a combination of these for the system of interest (manufacturing or process plant, unit or equipment).

The data-driven models include models built using statistical, machine learning or deep learning techniques such as variants of regression (multiple linear regression, stepwise regression, forward regression, backward regression, partial least squares regression, principal component regression, Gaussian process regression, polynomial regression, etc.), decision tree and its variants (random forest, bagging, boosting, bootstrapping), support vector regression, k-nearest neighbors regression, spline fitting or its variants (e.g. multi adaptive regression splines), artificial neural networks and it variants (multi-layer perceptron, recurrent neural networks & its variants e.g. long short term memory networks, and convolutional neural networks) and time series regression models. Further, the data-driven models also include statistical, machine learning or deep learning based one-class or multi-class classification, scoring or diagnosis models such as principal component analysis, Mahalanobis distance, isolation forest, random forest classifiers, one-class support vector machine, artificial neural networks and its variants, elliptic envelope and auto-encoders (e.g. dense auto-encoders, LSTM auto-encoders). The data-driven models can be point models (that do not consider temporal relationship among data instances for predictions) or time series models (that consider temporal relationship among data instances for predictions).

Furthermore, the data-driven models also include reduced-order models or response surface models of physics-based models. Response variables include key process parameters in process plants and can be one or more of productivity, yield, cycle time, energy consumption, waste generation, emissions, quality parameters, condition of equipment, availability, mean time between failures, number of unplanned shutdowns, cost of operation, cost of maintenance, or a weighted combination of the above that is indicative of the condition of the plant, process and/or equipment. The predictions from various models aid the plant operator or engineer to take informed decisions concerning the operation of the plant, to keep a check on possible anomalies, to classify the state/health of the plant, to identify the root cause of detected anomalies, to estimate remaining useful life of various processes or equipment, and to optimize the operation in order to achieve desired levels of key process parameters.

It is to be noted that the system (200) is configured to perform predictions, wherein the predictions are obtained using the selected at least one active prediction, detection, classification, diagnosis or prognosis model for the plurality of pre-processed real-time and non-real-time data. It would be appreciated that the plurality of prediction, detection, classification, diagnosis and prognosis models includes one or more data-driven models, one or more physics-based models and one or more hybrid models.

In the preferred embodiment, the computation module (216) of the system (200) is configured to compute a model quality index (MQI) for each of the plurality of models using the one or more predicted values and actual values of each of the one or more response variables. The MQI is computed for one or more instances of the received the plurality of real-time and non-real-time data. The predictions from the models are compared with an actual value or the ground truth to compute model quality index (MQI), wherein the MQI can be different for each of the plurality of models.

The MQI is calculated for each instance or a batch of instances of data received from the plant. The MQI could be one or a weighted combination of the following performance metrics in such a way that higher the value of MQI, better is the performance of the model:
Error metrics (absolute error, absolute percentage error, root mean square error, etc.)
Percentage of points within ±α % error
Coefficient of determination
Customized performance metrics (e.g. Hit Rate)
Precision, Recall, Overall accuracy, F-score
Area under ROC (receiver operating characteristic) curve
True Positive Rate
False Positive Rate
Missed Detection Rate

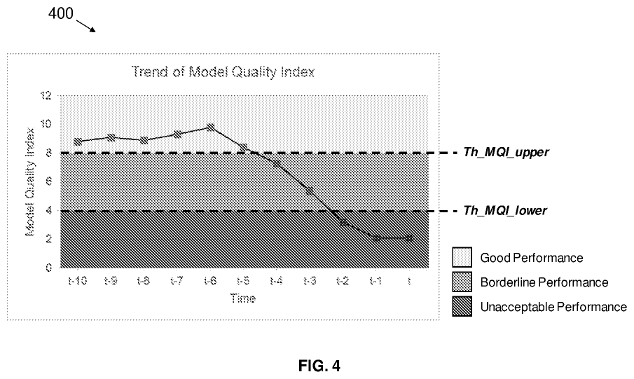

Referring FIG. 4, a graphical representation to show MQI thresholds. Wherein, the MQI can be different for each output from the active models and is customizable by the user. MQI will have at least one threshold/cutoff. In FIG. 4, Th_MQI_upper and Th_MQI_lower are obtained while training the prediction, detection, diagnosis, classification or prognosis models and/or set by the plant operator/engineer. For every time instance, the computed MQI is compared against its threshold(s). If the computed MQI value is above the threshold value(s), there is no drift in model accuracy and the predictions continue. If the MQI of the models is in between the lower threshold (Th_MQI_lower) and the upper threshold (Th_MQI_upper), the performance of the models is borderline. If the MQI of the models is below the lower threshold (Th_MQI_lower), the performance of the models is unacceptable.

In the preferred embodiment, the drift determination module (218) of the system (200) is configured to determine a drift in performance of each of the plurality of models based on one or more predefined thresholds of MQI. The drift in accuracy of each of plurality of prediction, detection, classification, diagnosis and prognosis models is based on one or more predefined thresholds of the computed MQI. It would be appreciated that if the computed MQI value of the plurality of prediction models is above the one or more predefined threshold values, there is no drift in the accuracy of each of plurality of prediction, detection, diagnosis and prognosis models.

In the preferred embodiment, the diagnostic module (220) of the system (200) is configured to diagnose the plurality of prediction models to identify at least one cause of the determined drift in the performance of the plurality of models using the real-time data, and key performance parameters related to process and equipment of the industrial manufacturing plant.

In the preferred embodiment, the pre-adaptive learning module (222) of the system (200) is configured to activate a pre-adaptive learning process based on the identified cause of the drift in the performance of the plurality of models, wherein the pre-adaptive learning computes MQI for each of subset of plurality of models.

In one aspect, if the model performance is in the borderline or unacceptable region for at least ‘n’ consecutive instances, the model performance is said to have drifted. Model drift diagnosis is then carried out to identify possible root causes for the drift in performance. If the drift in the model performance is neither due to a sensor fault/failure nor due to a process or an equipment fault, there is a need to change the active model and pre-adaptive learning is initiated. In the pre-adaptive learning process, ‘k’ relevant prediction, detection, classification, diagnosis or prognosis models are selected from the models database based on the current plant operation, input raw materials, condition of the process, health of the equipment and environmental conditions. For example, models that are specific for a certain type of raw material (e.g. iron ore from source ‘A’) or a certain environmental condition (e.g. ambient temperature below 15° C.) will be selected depending on the current operation of the plant and the environmental conditions. The models database is part of the adaptive learning knowledge base and is generated using the first set of data from multiple plants having the same/similar nature and function.

The predictions of response variables are estimated using the ‘k’ models for a combination of the first set of data and the second set of data. The first set of data is the data on which the active model was trained, and the second set of data is the data accumulated due to plant operation from the time of activation of the active model until the time pre-adaptive learning is initiated. The second set of data includes the instances of data for which the MQI is below the upper or lower thresholds. The first set of data represents the historical behavior of the industrial plant while the second set of data represents the latest behavior of the plant. The percentages of the first set of data and the second set of data used for pre-adaptive learning is predetermined (e.g. 10% the first set of data and 90% the second set of data); the percentages can also be learnt from the operation of the plant and can be modified by the user. For each of the ‘k’ models, the MQI is computed by comparing the predictions and the actual values or the ground truth of response variables. Each of the ‘k’ MQI values from the models are compared against the MQI thresholds. For any of the ‘k’ models, if the MQI is above the thresholds, the at least one model (typically the model with the highest MQI) among those is recommended for activation for subsequent predictions. The previously active model is recommended for deactivation. If the MQI for any of the ‘k’ models is not above the MQI thresholds, then the process of adaptive learning is triggered. The user is notified of the initiation of adaptive learning.

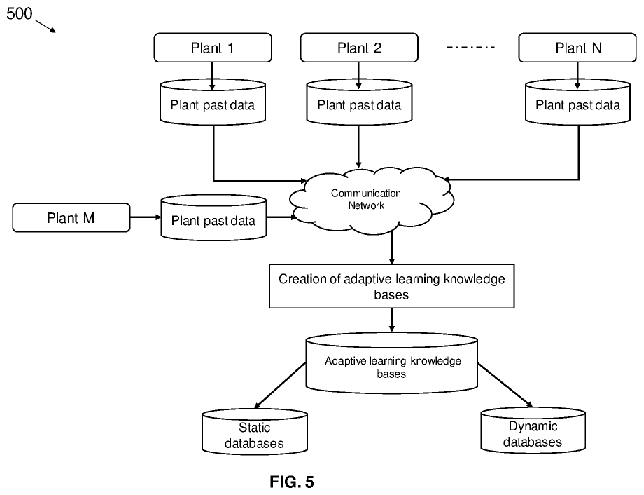

Referring FIG. 5, a functional block diagram (500) to illustrate creation of adaptive learning knowledge base. The first set of data (operations data, data from the laboratories, environment data, maintenance data, soft-sensed data estimated using physics-driven or data-driven soft sensors, etc.) from multiple plants of similar nature and function located in the same geographical location or at multiple geographical locations is used to create the adaptive learning knowledge base. The first set of data residing in multiple databases in their respective plants can be brought to a common processor via a data communication network. The adaptive learning knowledge base consist of two types of databases viz. static databases and dynamic databases.

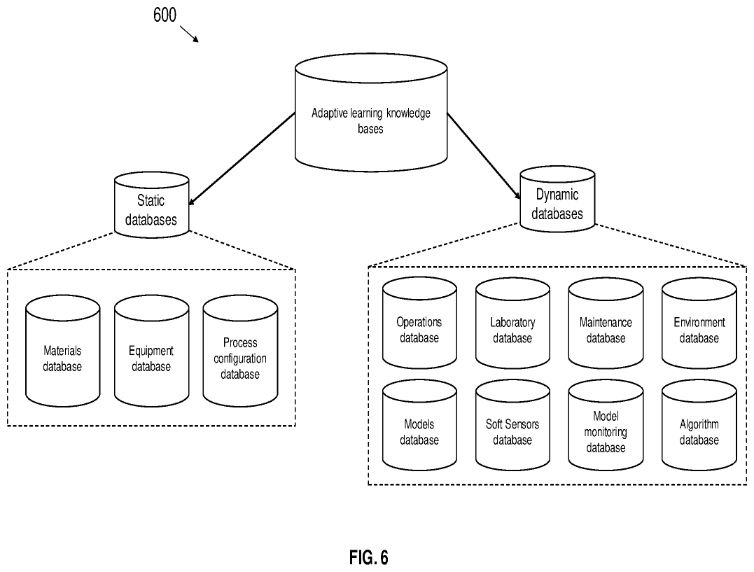

Referring FIG. 6, wherein the static databases comprise of data and information that do not vary with time such as materials database that consists of static properties of raw materials, byproducts and end-products, emissions, etc., an equipment database that consists of equipment design data, details of construction materials, etc., and a process configuration database that consists of process flowsheets, equipment layout, control and instrumentation diagrams, etc.

Further, the dynamic databases comprise of data and information that is dynamic in nature and are updated either periodically or after every adaptive learning cycle. Dynamic databases comprise of an operations database that consists of process variables, sensor data and knowledge derived from the same, a laboratory database that consists of properties of raw materials, byproducts and end-products obtained via tests at the laboratories, a maintenance database that consists of condition of the process, health of the equipment, maintenance records indicating corrective or remedial actions on various equipment, etc., an environment database that consists of weather and climate data such as ambient temperature, atmospheric pressure, humidity, dust level, etc.

The dynamic databases further comprise of a models database, soft sensors database, model monitoring database and algorithm database. It is to be noted that the models database consists of data-driven, physics-based and hybrid models, and associated training, test and validation data, performance metrics of the models and visual representation of model performance in the form of trend plots, parity plots, residual plots, histograms, etc. The soft sensors database consists of all physics-based and data-driven soft-sensor models and formulae relevant to the plants. Model monitoring database consists of model quality index formulae and thresholds for all data-driven, physics-based and hybrid models. Algorithm database consists of algorithms and techniques data-driven, physics-based and hybrid models, and solvers for physics-based models, hybrid models and optimization problems.

Herein, both the static and the dynamic adaptive learning databases are used for continuous monitoring of the various models of response variables, and adaptive learning of the prediction, detection, classification, diagnosis and prognosis models. Relevant dynamic databases e.g. models database, operations and model monitoring database are updated either after each adaptive learning cycle or at pre-determined intervals (e.g. every 30 minutes). It would be appreciated that the at least one prediction model is part of an adaptive learning knowledge base and is generated using historical data from one or more industrial manufacturing plants having the same nature and function but could be of different design capacities and located at different geographical locations.

In the preferred embodiment, the adaptive learning module (226) of the system (200) is configured to trigger an adaptive learning process based on the MQI of each of the subset of the plurality of models when MQI is below the one or more predefined MQI thresholds. Wherein, when the MQI of each of the considered plurality of prediction, detection, classification, diagnosis and prognosis models is below the one or more predefined thresholds MQI. Herein, the adaptive learning of the plurality of prediction models includes model diagnosis, model re-tuning, and model re-building and model-recreating. It would be appreciated that wherein the drift in the accuracy of each of the plurality of prediction, detection, classification, diagnosis and prognosis models is due to a fault in at least one sensor of the manufacturing plant or a process abnormality or an equipment fault, the adaptive learning process is not triggered.

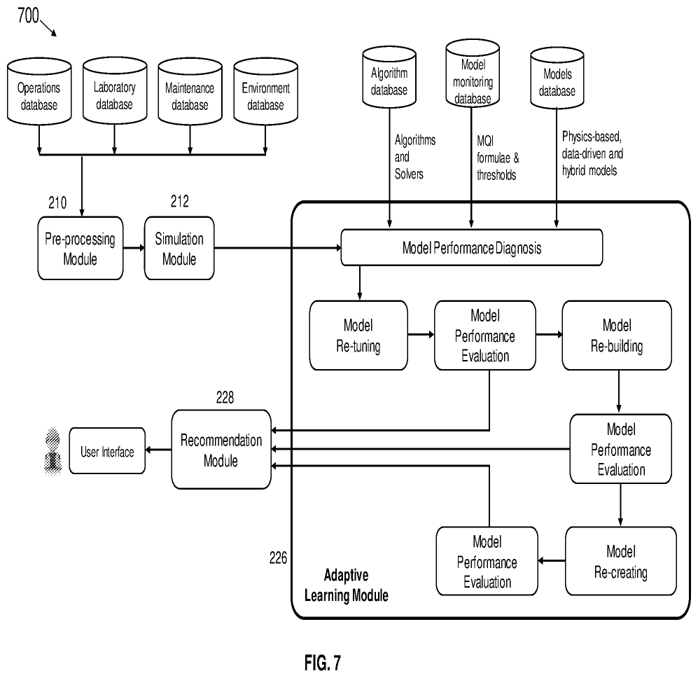

Referring FIG. 7, wherein a workflow (700) of the adaptive learning module (226) is illustrated. Once the process of adaptive learning is initiated, the active prediction, detection, classification, diagnosis or prognosis models are read from the plurality of model databases. The first set of data and the second set of data corresponding to the active models are also read from the operational and materials database. The first set of data refers to the data on which the active models were trained, and the second set of data is the data accumulated due to plant operation from the time of activation of the active models until the time pre-adaptive learning is initiated.

Further, the second set of data includes the instances of data for which the MQI is below the upper or lower thresholds. The second set of data accumulated since the last model activation is usually not clean and is pre-processed to remove redundant data, unify the sampling frequency, identify and remove outliers, impute missing data, and synchronize and integrate data from multiple data sources. Unification of frequency is performed either by averaging the variables with higher sampling frequency or by imputing the variables with lower sampling frequency.

In one example, wherein techniques such as Box & Whisker or z-score are used for outlier removal, while imputation is done by employing techniques such as exponential moving weighted average (EMWA), simple moving average (SMA) and the like. Synchronization and integration of data is carried out by considering the overall duration of the process in the plant as well as the residence time of materials in individual units. Data pre-processing may be carried out on the first set of data and second set of data either separately or together, data pre-processing may be followed by estimation of soft-sensed data using physics-based or data-driven soft sensors. Various statistical, machine learning and deep learning algorithms for training and testing data-driven models, and solvers for executing physics-based models are also read from the algorithm database. MQI formulae and thresholds relevant for the active models are read from the model monitoring database.

Further, if the active prediction, detection, classification, diagnosis, or prognosis models that requires adaptive learning are data-driven models, the steps involved in adaptive learning are model diagnosis, data selection, model re-tuning, model re-building and model-recreating. The sequence of steps to be followed depends on the nature of the first set of data and the second set of data and various criteria discussed in the subsequent sections. If the active models are physics-based models, adaptive learning involves the steps of data selection and model re-tuning. If the active models are hybrid models, the data-driven components of the models are subjected to adaptive learning via the data-driven route and the physics-based components of the models are subjected to adaptive learning via the physics-based route. After adaptive learning, both the adaptively learnt physics-based and data-driven components are placed back together and the hybrid model is tested for its performance.

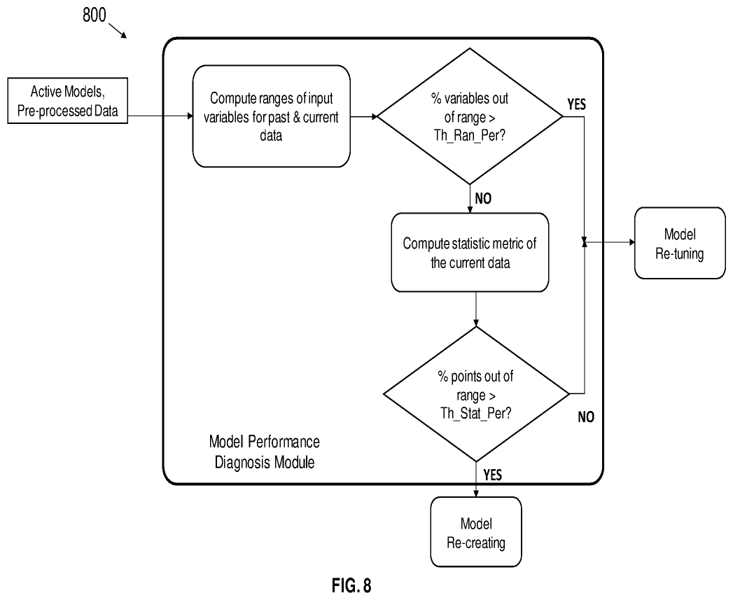

Referring FIG. 8, a functional block diagram wherein a model diagnosis is performed on data-driven models or data-driven components of hybrid models. It is carried out to detect the variables that have gone out of their training ranges, i.e., ranges of variables in the data on which the models were trained (the first set of data). In the model diagnosis, the ranges of all the input variables for the second set of data are computed and compared with the same from the first set of data. If the percentage of the input variables that are out of range is above a certain threshold, Th_Range_Per (available in adaptive learning knowledge base or configured by the user), data with only those variables that are already in the active models is used for the subsequent model re-tuning step. If the percentage of input variables that are out of range is below Th_Range_Per, statistical metrics such as T² metric from principal component analysis or the mahalanobis distance (MD) are computed for the second set of data. If the percentage of points in the second set of data exceeding the upper limit, Th_Stat of the statistical metric (available in adaptive learning knowledge base or configured by the user) is greater than a certain threshold, Th_Stat_Per (available in adaptive learning knowledge base or configured by the user), it implies that the operating regime of the industrial plant has changed substantially.

In the model diagnosis, data with all the variables available in the plant is used in the subsequent model re-creating step. If the percentage of points in the current exceeding the upper limit for the statistical metric is lower than Th_Stat_Per, it implies that the plant operating regime has not changed substantially even though some of the variables have gone out of range. In this case, data with only those variables that are already in the active models are used for the subsequent model re-tuning step.

It is to be noted that the model re-tuning is carried out on a combination of preprocessed the first set of data and the second set of data. The model re-building is invoked when the MQI of the re-tuned models are lower than the predefined thresholds of MQI. Herein, the model re-creating is invoked when the MQI of the re-built models are lower than the predefined thresholds of MQI or after model diagnosis based on predetermined criteria set out in the model diagnosis module.

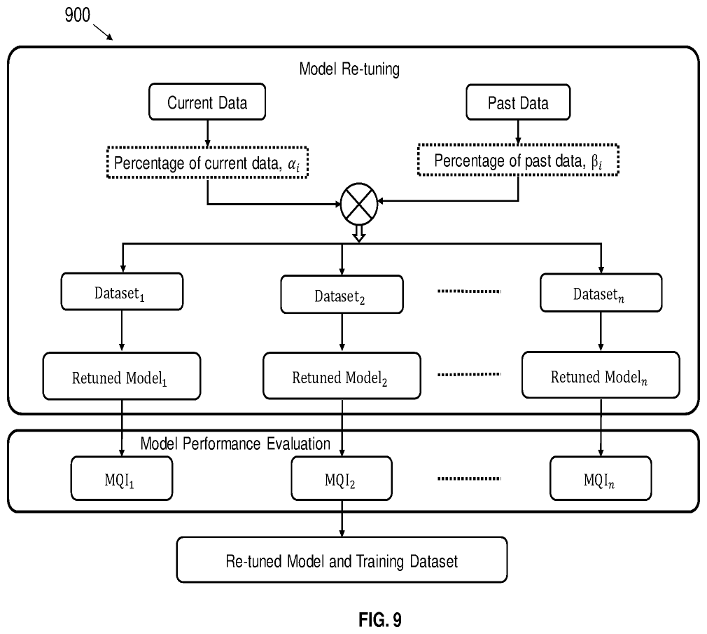

Referring FIG. 9, wherein a schematic diagram for model re-tuning is depicted. For data-driven models and data-driven components of hybrid models, the pre-processed first set of data and second set of data together are used for model re-tuning. Model re-tuning entails building the models again using the new data without changing either the variables used in the model or the technique used for building the models. Hyper-parameter tuning is also carried out while retuning the model.

In one aspect, if the existing active model was built using support vector regression, the same technique is used while re-tuning the model. While re-tuning, an optimum combination of the first set of data (that represents historical behavior of the plant) and the second set of data (that represents latest behavior of the plant) that results in the highest value of MQI is identified. The optimum combination of past and current for each model is identified via a grid search method or an optimization method.

In the FIG. 9, the grid search technique for identifying optimum combination of the first set of data and the second set of data during model re-tuning is depicted. According to this technique, ‘n’ training datasets are obtained by combining α % of the second set of data and β% of the first set of data (e.g. 90% of the second set of data and 20% of the first set of data). Here, α and β can take any value between 0 and 100. The number of training datasets ‘n’ is predetermined and can be modified by the user. The ‘n’ training datasets are used to re-tune the model using the same modeling techniques that was used to train the active data-driven models. After re-tuning, MQI is computed for each of the ‘n’ models using the validation dataset containing the predictions and the actual values of the response variables. Validation dataset is a portion of the second set of data (e.g. 30% of the second set of data or the part of the second set of data where the MQI is below the thresholds).

Herein, models out of the ‘n’ models that have an MQI greater than Th_MQI (either Th_MQI_upper or Th_MQI_lower as pre-configured by the user) are shortlisted and the model among these with the highest MQI is designated as the ‘re-tuned’ model corresponding to the active model. The dataset corresponding to the re-tuned model with optimum combination of a % of the second set of data (past data) and (3% of the first set of data is designated as the ‘training dataset’. It would be appreciated that the optimum values of α and β can also be obtained by solving an optimization problem of maximizing the MQI of the re-tuned models above the MQI threshold with α and β as manipulated variables using optimization techniques such as gradient search, linear programming, simulated annealing and evolutionary algorithms (e.g. genetic algorithms, particle swarm optimization, ant colony optimization, etc.).

It would be appreciated that the re-tuned model is added to the models database and activated for predictions in real-time as shown in FIG. 9. Other relevant dynamic databases of the adaptive learning knowledge base are updated by storing the training dataset, MQI corresponding to the re-tuned model, etc. After these steps, adaptive learning is terminated, and the user is informed of the same. Model predictions and model performance monitoring activities continue. On the other hand, if the MQI of none of the re-tuned models is greater than Th_MQI, then model re-building is invoked.

The procedure for model re-tuning of physics-based models and physics-based components of hybrid models is similar to that of data-driven models. Physics-based models use mathematical equations to approximate the complexity of physical systems. These equations may not always be complex enough to capture the entire physical reality. Therefore, ‘tuning parameters’ are typically used in physics-based models to ensure that predictions from these models as close as possible to physical reality. These tuning parameters may become obsolete due to changes in plant operation (input raw material changes, changes in operating strategy, wear and tear of equipment, maintenance activities, etc.) and the predictions of response variables drift from actual values. In this case, the tuning parameters are re-tuned using the first set of data and the second set of data to bring the predictions as close as possible to the actual values. Re-tuning of physics-based models is carried out by changing the tuning parameters within their acceptable ranges in such a way that MQI of the physics-based models improves beyond the predetermined thresholds. This is typically performed by solving the optimization problem of maximizing the MQI of physics-based solvers above the predetermined thresholds with tuning parameters as the manipulated variables and constraints on the values the tuning parameters can take. Solvers for physics-based models available in the algorithm database are used to solve the models when the tuning parameters are tuned.

Further, during re-tuning of parameters in physics-based models, an optimum combination of the first set of data and the second set of data that results in the highest MQI for physics-based models is identified. The optimum combination of current and the first set of data is identified via a grid search method or an optimization method.

Herein, the grid search technique and the optimization technique for identifying optimum percentages α % and β % of the first set of data and the second set of data respectively are the same as those described for re-tuning of data-driven models. After parameter re-tuning and identification of optimum combination of the first set of data and the second set of data, the at least one model with the highest MQI and whose MQI is greater than Th_MQI (either Th_MQI_upper or Th_MQI_lower as pre-configured by the user) is designated as the ‘ re-tuned model’. The dataset corresponding to the re-tuned model with optimum combination of α and β is designated as the ‘training dataset’. Further, the re-tuned physics-based models are added to the models database and activated for predictions in real-time. Other relevant dynamic databases of the adaptive learning knowledge base are updated by storing the training dataset, MQI corresponding to the re-tuned model, etc. After these steps, adaptive learning is terminated, and the user is informed of the same. Model predictions and model performance monitoring activities continue.

If the MQI of the re-tuned physics-based models are lower than Th_MQI, adaptive learning is terminated, and the user is informed of the same. The user may choose to relax the Th_MQI, add additional variables or use different first set of data and/or second set of data, and manually re-trigger the adaptive learning process. The user may also be provided recommendations on tests to be conducted on the plant to broaden the training region or to incorporate variables whose effect on the process is not captured sufficiently in the accumulated plant data.

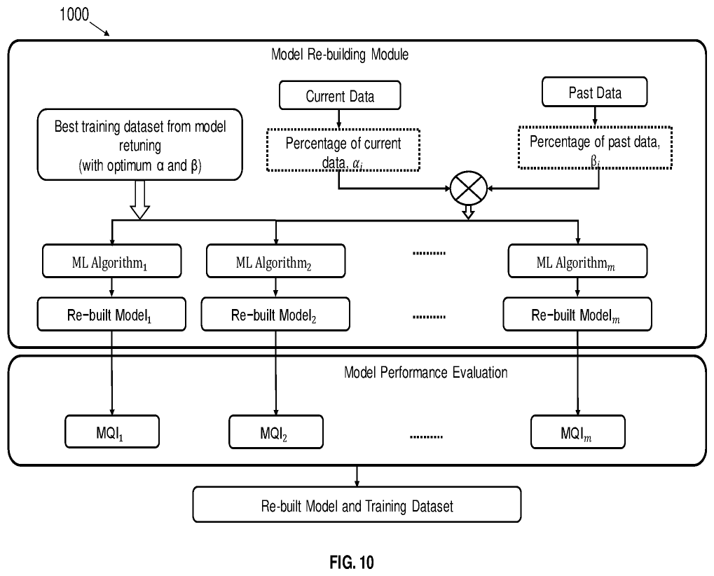

Referring FIG. 10 a schematic diagram to illustrate model re-building for data-driven models and data-driven components of hybrid model is depicted. The model re-building is invoked when the MQI of the at least one model after re-tuning is lower than Th_MQI. In this step as well, variables that are used in the active models are used. However, instead of using the modeling technique used in the active models, various other data-driven modeling techniques (‘m’ in number) are employed to re-build the active models. The model building algorithms stored in the models database are used. Even though, none of the models from re-tuning satisfy the MQI requirement, the combination of the first set of data and the second set of data corresponding to the possible MQI from re-tuning is considered to be a good data combination and may be used for model re-building. Alternatively, the optimum combination of α % of the second set of data and β% the first set of data can be identified again during model re-building using the grid search method or the optimization method.

It is to be noted that, depending on the modeling techniques used in the active models, the techniques used for model re-building include regression and its variants (multiple linear regression, stepwise regression, forward regression, backward regression, partial least squares regression, principal component regression, Gaussian process regression, polynomial regression, etc.), decision tree and its variants (random forest, bagging, boosting, bootstrapping), support vector regression, k-nearest neighbors regression, spline fitting or it variants (e.g. multi adaptive regression splines), artificial neural networks and it variants (multi-layer perceptron, recurrent neural networks & its variants (e.g. long short term memory networks), and convolutional neural networks) and time series regression models. The data-driven modeling techniques also include statistical, machine learning or deep learning based one-class or multi-class classification, scoring or diagnosis models such as principal component analysis, Mahalanobis distance, isolation forest, random forest classifiers, one-class support vector machine, artificial neural networks and its variants, elliptic envelope and auto-encoders (e.g. dense auto-encoders, LSTM auto-encoders). The techniques can be point techniques (that do not consider temporal relationship among data instances) or time series models (that consider temporal relationship among data instances).

In one aspect, wherein ‘m’ techniques to be used for model re-building are selected automatically from the models database (based on knowledge of applicability of certain techniques to a particular plant or unit) or by the user via the user interface. The models, ‘m’ in number, are built using the training dataset (having α % of pre-processed second set of data and β% of the first set of data where α′ and β′ are the optimal values identified from model re-tuning). Hyper-parameter tuning is also carried out for each modeling technique. MQI for each of the ‘m’ models is computed on the validation dataset using the actual values of response variables and the model predictions. All the re-built models whose MQI is greater than Th_MQI (either Th_MQI_upper or Th_MQI_lower as pre-configured by the user) are shortlisted and the model with the highest MQI is designated as the ‘re-built’ model. The training dataset corresponding to the re-built model is designated as the ‘training dataset’.

Further, the re-built model is added to the models database and activated for predictions in real-time. Other relevant dynamic databases of the adaptive learning knowledge base are updated by storing the training dataset, MQI corresponding to the re-built model, optimal hyper-parameters of the re-built model, etc. After these steps, adaptive learning is terminated, and user is informed of the same. Model predictions and model performance monitoring activities continue. If none of the ‘m’ models has an MQI that is greater than Th_MQI, the model re-creating step is invoked.

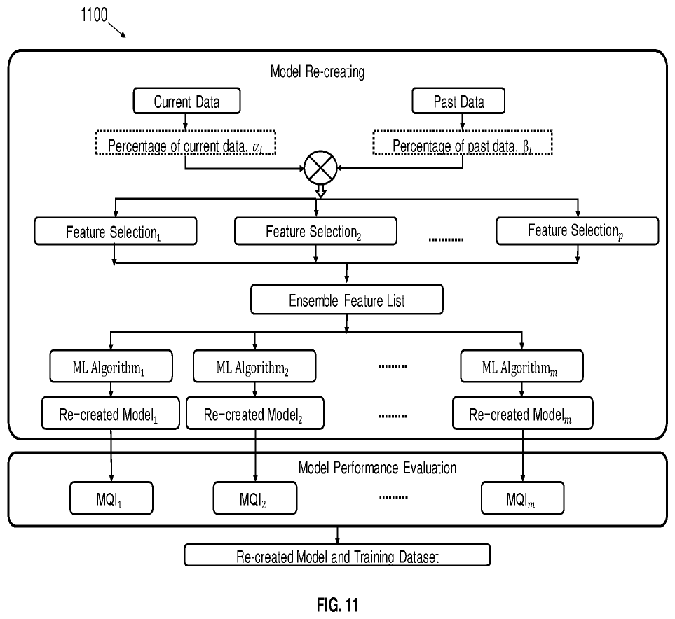

Referring FIG. 11, a schematic diagram to illustrate model re-creation for data-driven models and data-driven components of hybrid models is depicted. Herein, feature selection is performed on combinations of α % the second set of data and β % the first set of data. Feature selection is carried out using all the variables received from the plant and not just the variables used in the active models. Feature selection is carried out using ‘p’ feature selection techniques available in the models database. The feature selection techniques include model-based and non-model-based techniques and comprise of association mining, time series clustering, stepwise regression, random forest, supervised principal component analysis, support vector regression, etc. The feature selection techniques are selected automatically from the models database (based on knowledge of applicability of certain techniques to a particular plant or unit) or by the user via the user interface. The list of important variables/features obtained from each of the ‘p’ feature selection techniques is combined to arrive at an ensemble list of features. Important features from all the feature selection techniques may be combined using a weighted mean of score or ranks of individual features.

The ensemble list of features is used for building prediction models using ‘m’ model building algorithms available in the models database, selected automatically from the models database (based on knowledge of applicability of certain techniques to a particular plant or unit) or by the user via the user interface. Hyper-parameter tuning is also carried out for each modeling technique. MQI for each of the ‘m’ models is computed on the validation dataset using the actual values of response variables and the model predictions.

Herein again, an optimum combination of the first set of data and second set of data is identified via a grid search technique or an optimization technique. The grid search technique and the optimization technique for identifying optimum percentages α % and β % of the first set of data and second set of data respectively are the same as those used for model re-tuning. The at least one model after the steps of feature selection, model re-creation and selection of optimal combination of the first set of data and second set of data that has the highest MQI and whose MQI is greater than Th_MQI (either Th_MQI_upper or Th_MQI_lower as pre-configured by the user) is designated as the ‘re-created model’. The dataset corresponding to the re-created model with optimum combination of α % second set of data and β % of first set of data is designated as the ‘training dataset’.

Furthermore, the re-created model is added to the models database and activated for predictions in real-time. Other relevant dynamic databases of the adaptive learning knowledge base are updated by storing the training dataset, MQI corresponding to the re-created model, optimal hyper-parameters of the re-created model, etc. After these steps, adaptive learning is terminated, and user is informed of the same. Model predictions and model performance monitoring activities continue. If no re-created model with MQI greater than Th_MQI is obtained, adaptive learning is terminated, and the user is informed of the same. The user may choose to relax the Th_MQI, add additional variables or use different past and/or the second set of data and manually re-trigger the adaptive learning process. The user may also be provided recommendations on tests to be conducted on the plant to broaden the training region or to incorporate additional variables whose effect on the process is not sufficiently captured in the accumulated plant data.

It is to be noted that the above system is capable of performing simultaneous/bulk model monitoring and adaptive learning for multiple (e.g. few hundred) prediction, detection, classification, diagnosis and prognosis models depending on the complexity of the industrial manufacturing plant, the number of key process parameters associated with the plant and the number of models developed to capture the behavior of the plant. Further, the system is applicable to one or more unit operations or processes from manufacturing or process industries such as iron and steel making, power generation, pharma manufacturing, crude oil refineries, cement making, oil and gas production, fine chemical production, automotive production and so on, and the equipment could be any equipment used in the unit operations or processes in manufacturing and process industries, such as but not limited to valves, compressors, blowers, pumps, steam turbines, gas turbines, heat exchangers, chemical reactors, bio-reactors, condensers, boilers and automobile engines.

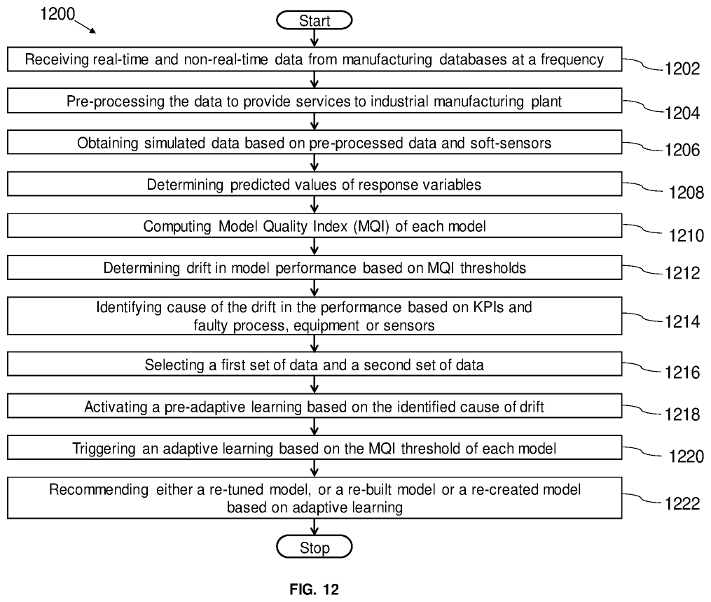

Referring FIG. 12 to illustrate a processor-implemented method (1200) for adaptive learning of models of the industrial manufacturing plant. It would be appreciated that the method (1200) is part of a model-based optimization and advisory device (MOAD) associated with the industrial manufacturing plant or a manufacturing system. The industrial manufacturing plant processes inputs in the form of raw materials, generates products, byproducts, and possibly solid and liquid waste and gaseous emissions. The industrial manufacturing plant usually operates in an environment, and environment conditions such as ambient temperature, pressure and humidity typically influence the operation of the plant. The MOAD interacts with the plant via a communication layer and receives data from several plant databases such as operations database, laboratory database, maintenance database, environment database and the like. It pre-processes the plant data, obtains simulated data using the pre-processed data and soft sensors, combines simulated data and pre-processed data to obtain integrated data, and uses the integrated data to provide services such as prediction, classification, detection, diagnosis and prognosis, process optimization, model monitoring and adaptive learning for active models (that can be physics-based, data-driven or hybrid) either continuously or on demand depending on its configuration.

Initially, at the step (1202), a plurality of data is received from one or more databases of an industrial manufacturing plant at a pre-determined frequency. The plurality of data comprises real-time and non-real-time data. The one or more databases include operations database, laboratory database, maintenance database and an environment database. It would be appreciated that the combination of the first set of data and the second set of data from the plant for model re-tuning, model re-building or model re-creating is chosen such that MQI of the re-tuned, re-built or re-created model is maximized.

In the preferred embodiment, at the next step (1204), the received plurality of data is pre-processed for verification of availability of received plurality of data, removal of redundant data, unification of sampling frequency, identification and removal of outliers, imputation of missing data, and synchronization and integration of a plurality of variables from one or more databases. It is to be noted that the plurality of models includes one or more data-driven models, one or more physics-based models and one or more hybrid models.

In the preferred embodiment, at the next step (1206), obtaining simulated data based on the pre-processed data and at least one soft sensor. Wherein, the at least one soft-sensor comprises a physics-based soft sensor and a data-driven soft sensor. It would be appreciated that the simulated data is integrated with pre-processed data to obtain integrated data.

In the preferred embodiment, at the next step (1208), determining one or more predicted values of each of the plurality of response variables using the obtained integrated data and a plurality of models. Herein, the plurality of models comprising at least one active model. Herein predictions refers to either of predicting the response of one or more variables/process parameters in the plant, detecting process or equipment anomalies, classifying the state/health of the process or equipment, diagnosing the root cause of process or equipment anomalies, and prognosing/estimating the remaining useful life (or time to failure) of a process or an equipment. It is to be noted that the predictions are estimated using the selected at least one active prediction, detection, classification, diagnosis or prognosis model for the plurality of pre-processed real-time data.

In the preferred embodiment, at the next step (1210), a model quality index (MQI) is computed for each of the plurality of models using the one or more predicted values and actual values of each of the one or more response variables. It would be appreciated that the MQI is computed for each instance or a batch of instances of the received the plurality of real-time and non-real-time data. Herein, the predictions are compared with actual values or ground truth to compute model quality index (MQI), wherein, the MQI can be different for each of the plurality of prediction, detection, classification, diagnosis and prognosis models.

In the preferred embodiment, at the next step (1212), determining a drift in performance of each of the plurality of models based on one or more predefined thresholds of MQI. The drift in accuracy of each of the plurality of models is determined based on one or more predefined threshold values of the computed MQI. It is to be noted that there would be no drift in the plurality of models if the computed MQI value is above the one or more predefined threshold values.

In the preferred embodiment, at the next step (1214), identifying at least one cause of the determined drift in the performance of the plurality of models using the real-time data, and key performance parameters related to process and equipment of the industrial manufacturing plant. It is to be noted that the drift in MQI could be due to one or more faults in the process, equipment or sensors. If the drift is due to either of faulty process, equipment or sensors, the user is informed of the same and the subsequent steps of data selection and pre-adaptive learning are not carried out.

In the preferred embodiment, at the next step (1216), selecting a first set of data and a second set of data of the industrial manufacturing plant. Wherein the first set of data comprises of real-time and non-real-time data used for training of the plurality of models and the second set of data comprises of real-time and non-real-time data accumulated due to plant operation since activation of the plurality of models.

In the preferred embodiment, at the next step (1218), activating a pre-adaptive learning based on the identified cause of the drift in the performance of the plurality of models. The pre-adaptive learning comprises identifying a subset of each of the plurality of models based on input raw materials, condition of the process, health of the equipment and environmental conditions, computing the MQI for each subset of the plurality of models using the first set of data and the second set of data, shortlisting models whose MQI are above the predetermined thresholds and activating the at least one shortlisted model with the highest MQI for execution.

In the preferred embodiment, at the next step (1220), an adaptive learning is triggered when the MQI of each of the subset of the plurality of models is below the one or more predefined MQI thresholds. Further, the adaptive learning of the plurality of models includes data pre-processing, soft-sensor estimation, model diagnosis, model re-tuning, model re-building and model re-creating. Herein, the model re-tuning is carried out based on a combination of selected plurality of the first set of data and the second set of data, and the model re-building is invoked when the MQI of the re-tuned models is lower than the predefined thresholds of MQI. It would be appreciated that the model re-creating is invoked when the MQI of the re-built models is lower than the predefined thresholds of MQI or after model diagnosis based on predetermined criteria.

In the preferred embodiment, at the last step (1222), recommending at least one model for activation in the industrial manufacturing plant based on adaptive learning of the plurality of models, wherein the at least one model includes a re-tuned model, a re-built model and a re-created model. It would be appreciated that the model re-tuning, model re-building and model re-creating are successive processes when the MQI of models from the earlier process is lower than the predefined MQI thresholds. The model re-tuning of the plurality of models is carried out based on combination of the first set of data and the second set of data of the industrial manufacturing plant without changing the input variables and the learning techniques used in the plurality of models.

It is to be noted that the model re-building of the plurality of models is carried out based on combination of the first set of data and the second set of data of the industrial manufacturing plant using a plurality of learning techniques without changing the input variables used in the plurality of models. The model re-creating of the plurality of models is carried out based on combination of the first set of data and the second set of data of the industrial manufacturing plant using a plurality of learning techniques and new variables identified through feature selection techniques.

The written description describes the subject matter herein to enable any person skilled in the art to make and use the embodiments. The scope of the subject matter embodiments is defined by the claims and may include other modifications that occur to those skilled in the art. Such other modifications are intended to be within the scope of the claims if they have similar elements that do not differ from the literal language of the claims or if they include equivalent elements with insubstantial differences from the literal language of the claims.

The embodiments of present disclosure herein addresses unresolved problem of handling the deteriorating performance of physics-based models or data-driven models deployed in industrial manufacturing plants over time due to factors such as changes in equipment/plant due to maintenance activities, ageing (wear and tear) of equipment, changes in operating strategy of the plant, changes in raw materials/inputs, malfunctioning (or failure) of key sensors and process/equipment abnormalities. Due to these reasons, the model predictions may drift leading to drop in performance accuracy of the model. In such cases, the models would not be effective for carrying out online monitoring, diagnostics and optimization. In cases, where the key sensors fail or the process is abnormal, model predictions would not be generated, leading to failure of the online monitoring, diagnostics and optimization procedure. The embodiments herein provide a system and method for an adaptive learning (i.e. automatic monitoring and upkeep of models) of the physics-based models, data-driven models and hybrid models in order to prevent faulty predictions. Moreover, the embodiments herein further provide an automatic identification of performance drift, diagnosis of the drift, automatic selection of appropriate first set of data and second set of data and, automatic re-tuning, re-building and re-creating of physics-based models, data-driven models and hybrid models.

It is to be understood that the scope of the protection is extended to such a program and in addition to a computer-readable means having a message therein; such computer-readable storage means contain program-code means for implementation of one or more steps of the method, when the program runs on a server or mobile device or any suitable programmable device. The hardware device can be any kind of device which can be programmed including e.g. any kind of computer like a server or a personal computer, or the like, or any combination thereof. The device may also include means which could be e.g. hardware means like e.g. an application-specific integrated circuit (ASIC), a field-programmable gate array (FPGA), or a combination of hardware and software means, e.g. an ASIC and an FPGA, or at least one microprocessor and at least one memory with software modules located therein. Thus, the means can include both hardware means, and software means. The method embodiments described herein could be implemented in hardware and software. The device may also include software means. Alternatively, the embodiments may be implemented on different hardware devices, e.g. using a plurality of CPUs.

The embodiments herein can comprise hardware and software elements. The embodiments that are implemented in software include but are not limited to, firmware, resident software, microcode, etc. The functions performed by various modules described herein may be implemented in other modules or combinations of other modules. For the purposes of this description, a computer-usable or computer readable medium can be any apparatus that can comprise, store, communicate, propagate, or transport the program for use by or in connection with the instruction execution system, apparatus, or device.

The illustrated steps are set out to explain the exemplary embodiments shown, and it should be anticipated that ongoing technological development will change the manner in which particular functions are performed. These examples are presented herein for purposes of illustration, and not limitation. Further, the boundaries of the functional building blocks have been arbitrarily defined herein for the convenience of the description. Alternative boundaries can be defined so long as the specified functions and relationships thereof are appropriately performed. Alternatives (including equivalents, extensions, variations, deviations, etc., of those described herein) will be apparent to persons skilled in the relevant art(s) based on the teachings contained herein. Such alternatives fall within the scope and spirit of the disclosed embodiments. Also, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items. It must also be noted that as used herein and in the appended claims, the singular forms “a,” “an,” and “the” include plural references unless the context clearly dictates otherwise.

Furthermore, one or more computer-readable storage media may be utilized in implementing embodiments consistent with the present disclosure. A computer-readable storage medium refers to any type of physical memory on which information or data readable by a processor may be stored. Thus, a computer-readable storage medium may store instructions for execution by one or more processors, including instructions for causing the processor(s) to perform steps or stages consistent with the embodiments described herein. The term “computer-readable medium” should be understood to include tangible items and exclude carrier waves and transient signals, i.e., be non-transitory. Examples include random access memory (RAM), read-only memory (ROM), volatile memory, nonvolatile memory, hard drives, CD ROMs, DVDs, flash drives, disks, and any other known physical storage media.

1. A processor-implemented method comprising steps of:
receiving, via an input/output interface, a plurality of data from one or more databases of an industrial manufacturing plant at a pre-determined frequency, wherein the plurality of data comprises real-time data and non-real-time data;
pre-processing, via the one or more hardware processors, the received plurality of data for identification and removal of outliers, imputation of missing data, and synchronization and integration of a plurality of variables from one or more databases;
obtaining, via the one or more hardware processors, simulated data based on the pre-processed data and using at least one soft sensor, wherein the at least one soft-sensor comprises a physics-based soft sensor and a data-driven soft sensor, wherein the simulated data is integrated with pre-processed data to obtain integrated data;
determining, via the one or more hardware processors, one or more predicted values of each of a plurality of response variables using the integrated data and a plurality of models, wherein the plurality of models comprising at least one active model, wherein the plurality of response variables include one or more key performance parameters of the industrial manufacturing plant;
computing, via the one or more hardware processors, a model quality index (MQI) for each of the plurality of models by comparing the determined one or more predicted values and one or more actual values of each of the plurality of response variables;
determining, via the one or more hardware processors, a drift in performance of each of the plurality of models based on one or more predefined thresholds of MQI, wherein the computed MQI of each of the plurality of models is compared with the predefined thresholds of MQI for each of the plurality of models;
identifying, via the one or more hardware processors, at least one cause of the determined drift in the performance of the plurality of models using one or more key performance parameters of the industrial manufacturing plant;
selecting, via the one or more hardware processors, a first set of data and a second set of data out of the plurality of data of the industrial manufacturing plant, wherein the first set of data is used for training of the plurality of models and the second set of data is stored since activation of the plurality of models;
activating, via the one or more hardware processors, a pre-adaptive learning to compute MQI for each subset of the plurality of models based on the selected first set of data and second set of data, and the identified cause of the drift in the performance of the plurality of models;
triggering, via the one or more hardware processors, an adaptive learning based on the MQI of each subset of the plurality of models when the MQI is below the one or more predefined MQI thresholds, wherein the adaptive learning of the plurality of models includes model performance diagnosis, model re-tuning, model re-building, and model-recreating on the selected first set of data and the second set of data; and
recommending, via the one or more hardware processors, at least one model for activation in the industrial manufacturing plant based on the adaptive learning of the plurality of models, wherein the at least one model includes a re-tuned model, a re-built model, and a re-created model.

2. The method of claim 1, wherein the plurality of models includes one or more prediction models, one or more detection models, one or more classification models, one or more diagnostic models and one or more prognostic models.

3. The method of claim 1, wherein each of the plurality of models is either a physics-based model or a data-driven model or a hybrid physics plus data-driven model.

4. The method of claim 1, wherein the pre-processing of the received plurality of data is also for verification of availability of the received plurality of data, removal of redundant data, and unification of sampling frequency.

5. The method of claim 1, wherein the pre-adaptive learning comprises of:
identifying, via the one or more hardware processors, a subset of each of the plurality of models based on input raw materials, condition of the process, health of the equipment and environmental conditions;
computing, via the one or more hardware processors, the MQI for each subset of the plurality of models; and
activating, via the one or more hardware processors, the at least one model with a highest MQI from the computed MQI for each subset of the plurality of models for the execution.

6. The method of claim 1, wherein the model re-tuning, model re-building and model re-creating are successive processes when the MQI of each of the plurality of models from the earlier processes is lower than the predefined MQI thresholds.

7. The method of claim 1, wherein the model re-tuning of each of the plurality of models is carried out based on a combination of the selected first set of data and second set of data of the industrial manufacturing plant without changing the input variables and the learning techniques used in the plurality of models.

8. The method of claim 1, wherein the model re-building of the plurality of models is carried out based on combination of the first set of data and the second set of data of the industrial manufacturing plant using a plurality of learning techniques without changing the input variables used in the plurality of models.

9. The method of claim 1, wherein the model re-creating of the plurality of models is carried out based on combination of the first set of data and the second set of data of the industrial manufacturing plant using a plurality of learning techniques and new variables identified through at least one feature selection technique.

10. The method of claim 1, wherein the combination of the first set of data and the second set of data for model re-tuning, model re-building or model re-creating is chosen such that MQI of the re-tuned model, re-built model, or re-created model is maximized.

11. A system comprising:
an input/output interface configured to receive a plurality of data from one or more databases of an industrial manufacturing plant at a pre-determined frequency, wherein the plurality of data comprises real-time and non-real-time data;
at least one memory storing a plurality of instructions; and
one or more hardware processors communicatively coupled with the at least one memory, wherein the one or more hardware processors are configured to execute the plurality of instructions stored in the at least one memory to:
pre-process the received plurality of data for verification of availability of the received plurality of data, removal of redundant data, unification of sampling frequency, identification and removal of outliers, imputation of missing data, and synchronization and integration of a plurality of variables from one or more databases;
obtain simulated data based on the pre-processed data and at least one soft sensor, wherein the at least one soft-sensor comprises a physics-based soft sensor and a data-driven soft sensor, wherein the simulated data is integrated with pre-processed data to obtain integrated data;
determine one or more predicted values of each of a plurality of response variables using the integrated data and a plurality of models, wherein the plurality of models comprising at least one active model, wherein the plurality of response variables include one or more key process parameters of the industrial manufacturing plant;
compute a model quality index (MQI) for each of the plurality of models by comparing the determined one or more predicted values and one or more actual values of each of the plurality of response variables;
determine a drift in performance of each of the plurality of models based on one or more predefined thresholds of MQI, wherein the computed MQI of each of the plurality of models is compared with the predefined thresholds MQI for each of the plurality of models;
identify at least one cause of the determined drift in the performance of the plurality of models using one or more key performance parameters of the industrial manufacturing plant;
select a first set of data and a second set of data out of the plurality of data of the industrial manufacturing plant, wherein the first set of data is used for training of the plurality of models and the second set of data is accumulated since activation of the plurality of models;
activate a pre-adaptive learning to compute MQI for each subset of plurality of models based on the selected first set of data and second set of data and the identified cause of the drift in the performance of the plurality of models;
trigger an adaptive learning based on the computed MQI of each subset of the plurality of models when the computed MQI is below the one or more predefined MQI thresholds, wherein the adaptive learning of the plurality of models includes model performance diagnosis, model re-tuning, model re-building, and model-recreating on the selected the first set of data and the second set of data; and
recommend at least one model for activation in the industrial manufacturing plant based on the adaptive learning of the plurality of models, wherein the at least one model includes a re-tuned model, a re-built model, and a re-created model.

12. The system of claim 11, wherein the one or more databases include operations database, laboratory database, maintenance database and an environment database.

13. The system of claim 11, wherein the plurality of models include one or more prediction models, one or more detection models, one or more classification models, one or more diagnostic models and one or more prognostic models, wherein each of the plurality of models is either a physics-based model or a data-driven model or a hybrid physics plus data-driven model.

14. A non-transitory computer readable medium storing one or more instructions which when executed by a processor on a system, cause the processor to perform a method comprising steps of:
receiving, via an input/output interface, a plurality of data from one or more databases of an industrial manufacturing plant at a pre-determined frequency, wherein the plurality of data comprises real-time data and non-real-time data;
pre-processing, via one or more hardware processors, the received plurality of data for identification and removal of outliers, imputation of missing data, and synchronization and integration of a plurality of variables from one or more databases;
obtaining, via the one or more hardware processors, simulated data based on the pre-processed data and using at least one soft sensor, wherein the at least one soft-sensor comprises a physics-based soft sensor and a data-driven soft sensor, wherein the simulated data is integrated with pre-processed data to obtain integrated data;
determining, via the one or more hardware processors, one or more predicted values of each of a plurality of response variables using the integrated data and a plurality of models, wherein the plurality of models comprising at least one active model, wherein the plurality of response variables include one or more key performance parameters of the industrial manufacturing plant;
computing, via the one or more hardware processors, a model quality index (MQI) for each of the plurality of models by comparing the determined one or more predicted values and one or more actual values of each of the plurality of response variables;
determining, via the one or more hardware processors, a drift in performance of each of the plurality of models based on one or more predefined thresholds of MQI, wherein the computed MQI of each of the plurality of models is compared with the predefined thresholds of MQI for each of the plurality of models;
identifying, via the one or more hardware processors, at least one cause of the determined drift in the performance of the plurality of models using one or more key performance parameters of the industrial manufacturing plant;
selecting, via the one or more hardware processors, a first set of data and a second set of data out of the plurality of data of the industrial manufacturing plant, wherein the first set of data is used for training of the plurality of models and the second set of data is stored since activation of the plurality of models;
activating, via the one or more hardware processors, a pre-adaptive learning to compute MQI for each subset of the plurality of models based on the selected first set of data and second set of data, and the identified cause of the drift in the performance of the plurality of models;
triggering, via the one or more hardware processors, an adaptive learning based on the MQI of each subset of the plurality of models when the MQI is below the one or more predefined MQI thresholds, wherein the adaptive learning of the plurality of models includes model performance diagnosis, model re-tuning, model re-building, and model-recreating on the selected first set of data and the second set of data; and
recommending, via the one or more hardware processors, at least one model for activation in the industrial manufacturing plant based on the adaptive learning of the plurality of models, wherein the at least one model includes a re-tuned model, a re-built model, and a re-created model.
